(19) United States
(12) Patent Application Publication
(10) Pub. No.: US 2015/0343962 A1
(43) Pub. Date: Dec. 3, 2015

(54) MULTIMEDIA SCREEN SUPPORT NOTABLY FOR A MOTOR VEHICLE INSTRUMENT PANEL

(71) Applicant: RENAULT, Boulogne Billancourt (FR)

(72) Inventors: Alban LE LEIZOUR, Maule (FR); Thierry MARCEAU, Rueil Malmaison (FR); Christophe BERTRAND, Vacheresse Les Bones (FR)

(73) Assignee: RENAULT s.a.s., Boulogne Billancourt (FR)

(21) Appl. No.: 14/654,251

(22) PCT Filed: Dec. 13, 2013
(86) PCT No.: PCT/EP13/76509

§ 371 Date: Jun. 19, 2015

(30) Foreign Application Priority Data
Dec. 21, 2012 (FR) 1262557

(51) Int. Cl. B60R 11/02; H05K 5/00

(52) U.S. Cl. CPC B60R 11/0229; H05K 5/0017; B60R 2011/0005

(57) ABSTRACT

A multimedia screen support, notably for an instrument panel of a motor vehicle, including a casing in which a carriage slides between a retracted position inside the casing and a deployed position outside the casing, wherein the carriage supports a stand pivoted at its base between a position in which it is laid down against the carriage, allowing the carriage and the stand to be retracted into the casing, and a raised position for holding a multimedia screen bearing on a bottom ledge of the stand, the bottom ledge also being movable relative to the base of the stand pivoted on the carriage, between an upper position which frees space below the stand and a lower position for lowering the position of a multimedia screen, notably in order to limit the extent to which it protrudes above the top edge of the stand.

### TECHNICAL FIELD

The present invention relates to a multimedia screen support, notably for a motor vehicle instrument panel. The term “multimedia screen support” denotes a support capable of receiving any type of multimedia equipment, typically having a screen on one of its faces, this screen being, for example but not exclusively, of the touch screen type. The dimensions of this equipment are, for example, those of a tablet computer in a 7 to 13 inch format, or those of a telephone or personal digital assistant having a screen in a format typically in the range from 3 to 7 inches. The term “multimedia screen” is a generic term and is to be interpreted in a non-limiting manner, it being understood that a support capable of receiving this screen will be equally capable of receiving other articles in a similar format, for example a notebook, a road map, or the like.

### PRIOR ART

Instrument panels of family or utility vehicles are sometimes fitted with accessories for holding multimedia screens, notebooks, or other types of article having similar shapes and dimensions.

There are known supports of this type which can be deployed from and retracted into a housing in the instrument panel. If the object to be supported has dimensions corresponding to a 10-inch screen for example, equivalent to a diagonal measurement of about 25 cm, the screen support itself has similar dimensions, and therefore a housing with considerable overall dimensions has to be provided in the instrument panel to enable the support to be retracted. This is because the opening of the housing, at least, must allow the support to pass through. The depth of the support must also be large in order to receive the support in the retracted, or withdrawn, position. The instrument panel of a vehicle must also be fitted with many other items of equipment which cannot always be easily accommodated in a given space. The instrument panel is also subject to numerous constraints of visibility and ease of use. Therefore the aim is to reduce the overall dimensions of the multimedia screen support. This is true both as regards the retracted position, where the aim is to save space in the body of the instrument panel, and as regards the deployed position of the multimedia screen, where the aim is to minimize the concealment of the area on the front of the instrument panel (where various controls or pieces of equipment are located), or in the driver's field of view. It has also been observed that supports placed in the upper part of the instrument panel exacerbate the driver's loss of visibility, when a large-sized screen (measuring more than 7 inches, for example) conceals part of the field of view delimited by the windshield. Safety may therefore be affected by a screen that protrudes too far into the driver's field of view.

Moreover, multimedia screen supports provide for very limited adjustment which does not allow for the range of sizes of multimedia screens that may be installed, which vary from small-sized screens (measuring about 3 to 7 inches, for example) to larger-sized screens (measuring about 7 to 13 inches, for example). With these known supports, it is not possible to prioritize the driver's field of view, or to prioritize access to surrounding controls or accessories located on the instrument panel, according to the size of the screen.

### OBJECT OF THE INVENTION

The object of the invention is to overcome all or some of the aforementioned drawbacks by proposing a multimedia screen support, notably for an instrument panel of a motor vehicle, as well as an instrument panel fitted with a support of this type which is particularly compact in its overall size, notably in the position in which it is retracted or withdrawn into the instrument panel, and which allows easy adjustment for positioning the multimedia screen in a position chosen by the user, according to the overall dimensions of the screen and the requirements of visibility or access to various controls.

### SUBJECT OF THE INVENTION

For this purpose, the invention relates to a multimedia screen support, notably for an instrument panel of a motor vehicle, characterized in that it comprises a casing in which a carriage slides between a retracted position inside the casing and a deployed position outside the casing, characterized in that the carriage supports a stand pivoted at its base between a position in which it is laid down against the carriage, allowing the carriage and the stand to be retracted into the casing, and a raised position for holding a multimedia screen bearing on a bottom ledge of the stand, the bottom ledge also being movable relative to the base of the stand pivoted on the carriage, between an upper position which frees space below the stand and a lower position for lowering the position of a multimedia screen, notably in order to limit the extent to which it protrudes above the top edge of the stand.

As well as offering many possibilities of adjustment to allow for the multiple existing formats of multimedia screens, the support can be fully retracted into a space in the standardized “1 DIN” format, mainly provided in the casing adapted to receive the support. The support according to the invention also offers the possibility of adjusting the position of the support and of the screen held in this way, as the user chooses, so as to prioritize either visibility or access to adjacent equipment on the instrument panel, or so as to achieve a balance between these constraints.

According to other advantageous characteristics of the invention:
the casing has an opening in the standardized “1 DIN” format,
the stand has a rear face connected to the carriage by a stay that can be moved between a raised holding position and a retracted stowage position between the carriage and the stand in the laid-down position,
the bottom ledge has a substantially horizontal plate connected to a top part of the stand by substantially vertical guides sliding in apertures formed in the top part, a disengageable locking system being provided to keep the bottom ledge in its upper position or to release it therefrom,
the support has lateral blocks in the general shape of two fins projecting from a front face of the stand, these blocks being connected to a top part of the stand by drive means enabling the blocks to be moved between a separated configuration at a distance from the stand to a closer configuration next to the lateral edges of the stand, the drive means also being designed to provide combined movements of one block relative to the other,
the drive means comprise a system having double pinions mounted in a fixed way on a rotating shaft carried by the stand, each pinion interacting with a corresponding rack connected rigidly to one or other of the blocks, the number of teeth of the pinions being different for one and the other of the racks in such a way that the ratio R of the distances traveled by each of the blocks is other than 1,
the ratio R is in the range from 1.2 to 2, and notably R equals 1.5, the ratio being considered to be the ratio of the longest distance to the shortest distance traveled by the blocks,
the support comprises a solid wall extending the bottom ledge upward in a substantially perpendicular manner to the plate, this solid wall being inserted into the body of the stand when the bottom ledge is in the upper position, while it is exposed when the bottom ledge is in the lower position.

The invention also relates to a motor vehicle instrument panel characterized in that it comprises a multimedia screen support having all or some of the preceding characteristics.

### DISCLOSURE OF THE INVENTION

The invention will be understood more readily with the aid of the following description of a non-limiting example of the invention, with reference to the appended drawings, in which:

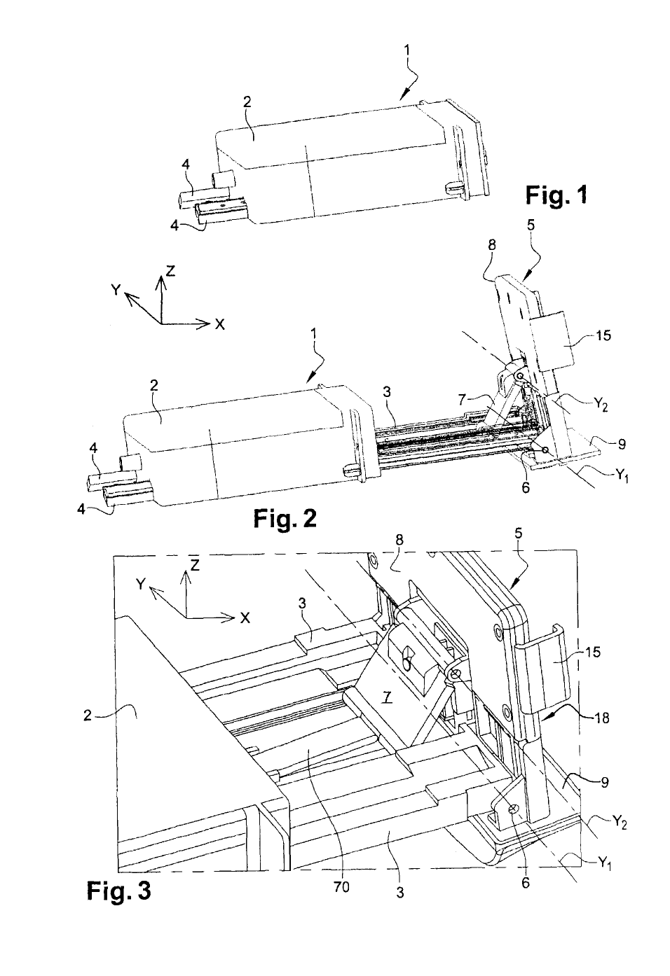

FIG. 1 shows a multimedia screen support according to the invention, the carriage and the stand being stowed in the retracted position inside the casing,

FIG. 2 shows the multimedia screen support according to the invention, the carriage being in the deployed position outside the casing, while the stand is in the raised position,

FIG. 3 is an enlarged view of a rear part of the stand, showing the area of the stay holding the stand in the raised position,

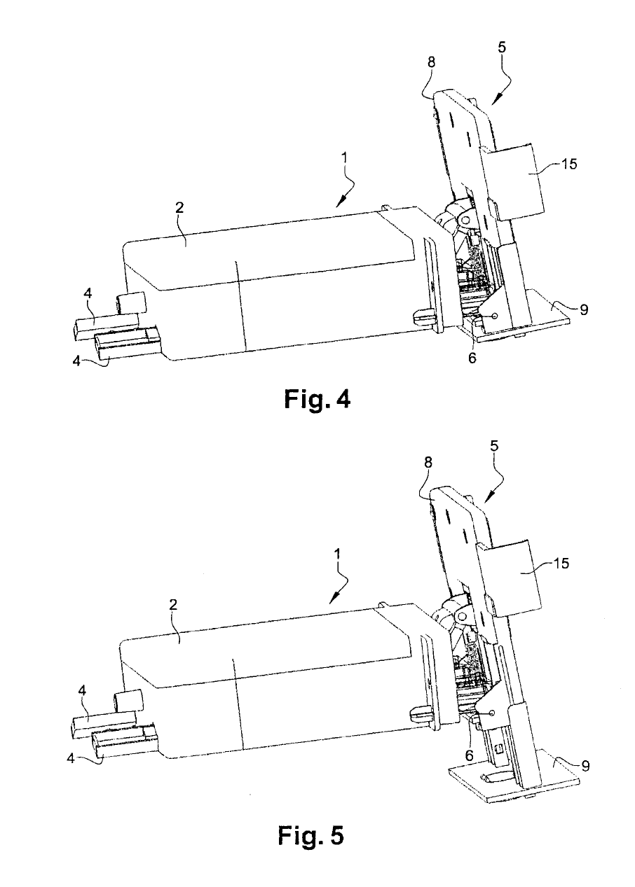

FIG. 4 shows the multimedia screen support of FIG. 2, in the situation of the standard use of the screen, the carriage being partially inserted into the casing, while the stand is in the raised position and bears against the casing, the bottom ledge then being in the upper position,

FIG. 5 is a view similar to that of FIG. 5, in which the bottom ledge of the stand is in the lower position,

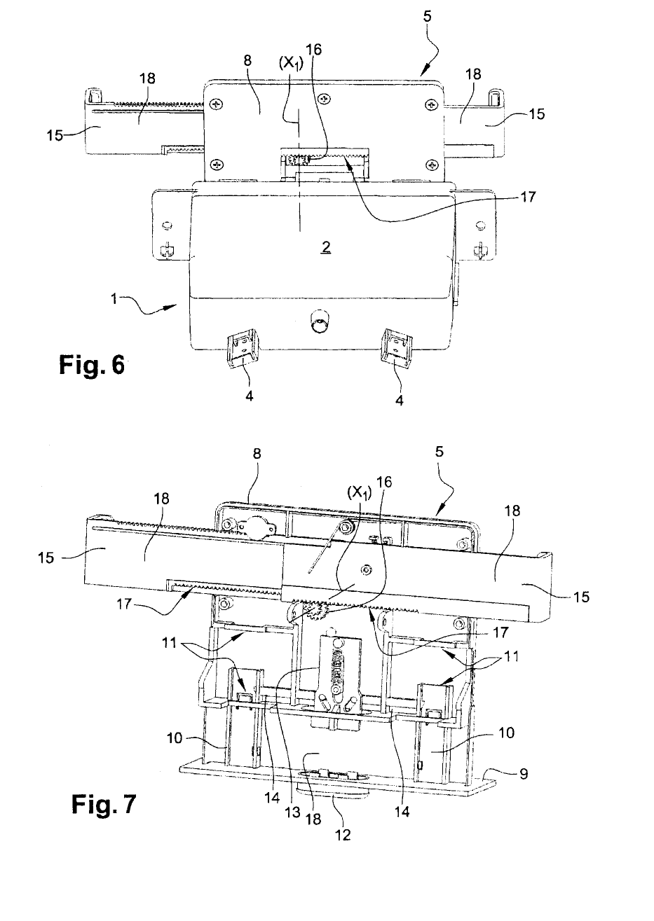

FIG. 6 is a rear view of the support of the invention, showing the lateral blocks in a separated position, and

FIG. 7 is a view of the rear part of the stand according to the invention on its own, without its rear panel, showing more precisely the guiding mechanism of the bottom ledge and the system for guiding/driving the lateral blocks.

The present text describes a multimedia screen support, typically intended for fitting to a motor vehicle instrument panel. In this context, and if not specified otherwise, the concepts of “front” and “rear” are used with reference to the passengers in the front of the vehicle. A “front” part faces toward these passengers, that is to say toward the rear of the vehicle, while a “rear” part faces in the opposite direction, toward the front of the vehicle. The conventional XYZ reference frame for a vehicle is also used hereafter, with X denoting the longitudinal direction of the vehicle running toward the rear of the vehicle, Y denoting the transverse direction of the vehicle oriented toward the right, and Z denoting the vertical direction oriented upwards.

FIG. 1 shows a multimedia screen support 1 according to the invention, notably for a motor vehicle instrument panel. The instrument panel and the multimedia screen are not shown. It will be understood that the term “multimedia screen” is generic and covers all types of multimedia devices having a format in the range from at least 3 inches to 13 inches, regardless of whether they are tablet computers, touchscreen telephones, or others. This support according to the invention is also capable of holding other types of objects, such as notebooks. In FIG. 1, the support is in the stowage position, that is to say fully retracted into a casing 2. The whole of the support according to the invention in this retracted configuration is contained within a space in the standardized “1 DIN” format.

The casing 2 has the general shape of a parallelepiped. The overall dimensions of its front end are entirely contained within a frame in “1 DIN” format. Similarly, in this retracted configuration, the whole support has a longitudinal dimension in the direction X substantially corresponding to the longitudinal dimension of conventional equipment (car radios or the like) in “1 DIN” format. Thus the casing 2 can be received in a housing having a corresponding shape and dimensions provided on the front of an instrument panel of a vehicle.

With reference to FIGS. 2 and 3, the support 1 comprises a carriage 3 mounted slidably in the longitudinal direction X, between a retracted position inside the casing 2 (FIG. 1) and a deployed position outside the casing 2 (FIGS. 2 and 3).

In the illustrated example, the carriage 3 is mounted slidably on two parallel rails 4 passing longitudinally through the casing 2, in a lower part of the casing.

In this example, the rails 4 protrude behind the casing 2, to allow the maximum extension of the carriage 3 in the deployed position, while being contained within the standardized “1 DIN” space. In a variant embodiment, they can be covered by part of the casing. As shown in FIG. 6, in this case the rails 4 are inclined to provide better positioning of the carriage and to take up the lateral play at Y.

The carriage 3 supports a stand 5 pivoted at its base about an axis Y1 substantially parallel to the transverse direction Y. The stand takes the form of a plate serving as the rear support for a multimedia screen. It is prolonged in its lower part by a bottom ledge on which the multimedia screen rests, as described below. The stand 5 is movable about the pivot 6 between a position in which it is laid down against the carriage 3 so that the carriage 3 and the stand 5 can be retracted into the casing 2, and a raised position for holding a multimedia screen bearing on a bottom ledge 6 of the stand 5. The laid-down position is substantially horizontal, that is to say parallel to the planes XY, while the raised position of the stand is substantially vertical or slightly inclined toward the rear. By way of non-limiting example, an angle of inclination of about 10° to 20° is entirely suitable.

The stand 5 is held in its vertical position by a stay 7 located at the rear of the stand 7. The stand 5 has a rear face connected to the carriage 3 by a stay 7 that can be moved between a raised holding position (FIGS. 2 and 3) and a retracted stowage position between the carriage 3 and the stand 5 in the laid-down position. The stay 7 has a first end pivoted on the rear face of the stand 5 about an axis Y2. It also has a second end forming a foot that slides on the carriage 3 in the longitudinal direction X. The sliding of the second end along the rail 3, in combination with the rotation of the stay 7 around the pivot at Y2, makes it possible to move the stand 5 between its laid-down position and its raised position. A system for fixing the stand 5 in the raised position is also provided. This system is composed of a connecting bar 70 pivoted on the carriage 3 and acting as a lever (FIG. 3). This connecting bar 70 is pivoted about an axis parallel to the transverse direction Y. As soon as the stay 7 has reached its raised position, one of the ends of the connecting bar 70 interacts with a corresponding recess formed at the second end of the stay 7. The connecting bar 70 is placed automatically in this position for locking the stay 7 by the action of a return means (not shown) interposed between the connecting bar 70 and the carriage 3.

The stand 5 further comprises a top part 8 which is directly pivoted at its base on the end of the carriage 3. The stand also comprises a bottom ledge 9 which is movable relative to the top part and therefore relative to the base of the stand 5, between an upper position, shown in FIG. 4, which frees space underneath the stand 5, and a lower position, shown in FIG. 5, for lowering the position of a multimedia screen, notably in order to limit the extent of its protrusion above the upper edge of the stand 5.

The bottom ledge 9 has a substantially horizontal plate connected to a top part of the stand by substantially vertical guides 10 sliding in the substantially vertical direction in recesses formed in the top part 8. Two parallel longitudinal guides 10 are spaced apart in the transverse direction Y. They are inserted into apertures 11 formed in walls or flanges formed on the top part 8 of the stand 5. Upper and lower apertures are provided to ensure that the bottom ledge is suitably retained and guided regardless of whether it is in the upper or lower position. Stops are provided to arrest the sliding of the bottom ledge 9 at a predetermined lower position. The downward movement of the bottom ledge 9 takes place by gravity, as soon as a locking system for retaining this bottom ledge 9 in the upper position has been disengaged to release the bottom ledge 9.

The locking system consists of a push button 12 located on the bottom ledge 9 and arranged so that it can be pushed upward by hand. This push button 12 interacts with a sliding piece 13 mounted on the top part 8 of the stand 5 (in a lower area thereof), this sliding piece being connected to the guides 10 by bars 14 placed on either side of the sliding piece 13 and arranged in the transverse direction Y. The ends of the bars 14 opposite the sliding piece 13 are adapted to penetrate into corresponding openings formed in the guides 10, and thus act as bolt and keeper systems for locking the guides 10 relative to the top part 8 of the stand 5 when the bottom ledge 9 is in the upper position. It should be noted that the ends of the bars 14 have a sloping shape, allowing automatic withdrawal from the corresponding openings under the action of an upward push of the bottom ledge 9.

The support also comprises lateral blocks 15 in the general shape of two fins projecting in the longitudinal direction X from the front face of the stand 5. These blocks 15 are connected to the top part 8 of the stand 5 by drive means for moving the blocks between a separated configuration, shown in FIGS. 6 and 7, at a distance from the stand 5 and a closer configuration, shown in FIGS. 2 and 5, next to the lateral edges of the stand 5. These drive means are also designed to provide combined movements of one block 15 relative to the other. These movements are asymmetrical, so that an accessory such as another telephone support can be placed near the multimedia screen support 1 of the invention. Thus, if this other support is located at one side of the support 1 according to the invention, the left side for example, it is advantageous for the retaining blocks 15 to be separated by a smaller movement on this side and by a larger movement on the other side. Thus, the area for receiving the multimedia screen is offset as a whole toward the opposite side, the right side for example, where there are fewer constraints in respect of overall dimensions.

This asymmetrical movement is produced by a system of double pinions 16 mounted on, and fixed with respect to, a rotating shaft carried by the top part 8 of the stand 5 (FIGS. 6 and 7). The rotation takes place about an axis X1 substantially parallel to the longitudinal direction X. These two pinions are fixed together with respect to rotation and form a two-stage gear wheel corresponding to different gear ratios. Each pinion interacts with a corresponding rack 17 connected rigidly to one or other of the blocks. The racks 17 are formed on arms 18 extending substantially in the transverse direction Y (FIGS. 6 and 7). The ratio of the distances traveled by the two lateral blocks 15 is typically in the range from 1.2 to 2, for example 1.5 (this being the ratio of the longer distance traveled, by the right-hand block 15 for example, to the smaller distance traveled, by the left-hand block for example).

The support 1 according to the invention further comprises a solid wall 18 extending the bottom ledge 9 upward in a manner substantially perpendicular to the plate forming the bearing face of the screen (FIGS. 3 and 7). This solid wall 18 is inserted into the body of the top part 8 of the stand 5 when the bottom ledge 9 is in the upper position, while it is exposed when the bottom ledge 9 is in the lower position.

The support 1 is used as follows: starting from a stowed configuration (FIG. 1), the user manually grasps a grip element positioned on the front face of the support, formed by the underside of the bottom ledge 9. The user pulls on this element, causing the carriage 3 to be moved to the deployed position. The user raises the stand 5 from its laid-down position to its raised position. Locking is provided by the frictional system arranged between the stay 7 and the connecting bar 70. The user pushes the carriage 1 back until the top of the stay 7 interacts with the upper edge of the casing 2 by bearing against it. The user then makes the desired adjustments, for example by lowering the bottom ledge 9 and/or by separating the lateral blocks 15. These movements are independent of one another.

The stowage of the support 1 in the casing 2 is carried out by a sequence of operations which is the reverse of that described above. The assembly composed of the carriage 3, the stand 5 (including the bottom ledge 9 and its lateral blocks 15) is retracted into the casing 2. A trim element for gripping may be attached and fixed to the lower face of the bottom ledge 9.

Clearly, the invention is not limited to the embodiments described above, but comprises all technical equivalents of these means.

1. A multimedia screen support, comprising a casing in which a carriage slides between a retracted position inside the casing and a deployed position outside the casing, wherein the carriage supports a stand pivoted at its base between a position in which said stand is laid down against the carriage, allowing the carriage and the stand to be retracted into the casing, and a raised position for holding a multimedia screen bearing on a bottom ledge of the stand, the bottom ledge also being movable relative to the base of the stand pivoted on the carriage, between an upper position which frees space below the stand and a lower position for lowering the position of a multimedia screen, in order to limit the extent to which said multimedia screen protrudes above the top edge of the stand.

2. The multimedia screen support as claimed in claim 1, wherein the casing has an opening in the standardized “1 DIN” format.

3. The multimedia screen support as claimed in claim 1, wherein the stand has a rear face connected to the carriage by a stay that can be moved between a raised holding position and a retracted stowage position between the carriage and the stand in the laid-down position.

4. The multimedia screen support as claimed in claim 1, wherein the bottom ledge has a substantially horizontal plate connected to a top part of the stand by substantially vertical guides sliding in apertures formed in the top part, a disengageable locking system being provided to keep the bottom ledge in its upper position or to release it therefrom.

5. The multimedia screen support as claimed in claim 1, comprising lateral blocks in the general shape of two fins projecting from a front face of the stand, these blocks being connected to a top part of the stand by drive means enabling the blocks to be moved between a separated configuration at a distance from the stand to a closer configuration next to the lateral edges of the stand, the drive means also being designed to provide combined movements of one block relative to the other.

6. The multimedia screen support as claimed in claim 5, wherein the drive means comprise a system having double pinions mounted in a fixed way on a rotating shaft carried by the stand, each pinion interacting with a corresponding rack connected rigidly to one or other of the blocks, the number of teeth of the pinions being different for one and the other of the racks in such a way that the ratio of the distances traveled by each of the blocks is other than 1.

7. The multimedia screen support as claimed in claim 6, wherein the ratio R is in the range from 1.2 to 2, and notably R equals 1.5, the ratio being considered to be the ratio of the longest distance to the shortest distance traveled by the blocks.

8. The multimedia screen support as claimed in claim 4, comprising a solid wall extending the bottom ledge upward in a substantially perpendicular manner to the plate, this solid wall being inserted into the body of the stand when the bottom ledge is in the upper position, while said solid wall is exposed when the bottom ledge is in the lower position.

9. An instrument panel of a motor vehicle, comprising a multimedia screen support as claimed in claim 1.
